(19) United States
(12) Patent Application Publication
(10) Pub. No.: US 2026/0052933 A1
(43) Pub. Date: Feb. 19, 2026

(54) MOUNTING DEVICE

(71) Applicant: Samsung Electronics Co., Ltd., Suwon-si (KR)

(72) Inventors: Tatsuya Ishimoto, Suwon-si (KR); Takahiro Tokumiya, Suwon-si (KR)

(21) Appl. No.: 19/083,722

(22) Filed: Mar. 19, 2025

(30) Foreign Application Priority Data
Aug. 15, 2024 (JP) 2024-135548

(51) Int. Cl. H01L 21/67

(52) U.S. Cl. CPC H01L 21/67132

(57) ABSTRACT

Provided is an apparatus for manufacturing a semiconductor device configured to attach an adhesive film to an attachment surface of a workpiece under a depressurized condition. The apparatus comprises a chamber including a housing and a cover detachably coupled to the housing, and a stage accommodated in the chamber and having a holding chuck configured to secure the workpiece and a first heater configured to heat the workpiece. The housing has a discharge opening which is configured to depressurize an interior of the chamber. The cover comprises an elastic layer, a cover body, and a cooler. The elastic layer is disposed at a lower surface of the cover body to face the holding chuck of the stage. The elastic layer is configured to secure the adhesive film. The elastic layer has a first surface configured to attach the adhesive film on the attachment surface of the workpiece. The elastic layer has a second surface which is facing away from the first surface. The lower surface of the cover body faces the second surface of the elastic layer. The cover body has a ventilation hole fluidly communicating with the second surface of the elastic layer. The cooler is in contact with the elastic layer.

### CROSS-REFERENCE TO RELATED APPLICATION

This application claims priority to and the benefit of Japan Patent Application No. 2024-135548 filed in the Japan Patent Office on Aug. 15, 2024, the entire contents of which is incorporated herein by reference.

### BACKGROUND OF THE INVENTION

### (a) Field of the Invention

The present invention relates to an apparatus for manufacturing a semiconductor device. Especially, the present invention relates to an apparatus for attaching a film to a workpiece. For example, the present invention relates to a mounting device.

### (b) Description of the Related Art

In the semiconductor manufacturing process, a thermal compression bonding (TCB) method is used to stack chips on a wafer, and an adhesive film having an insulating property is attached to the chips used therein to protect the chip surface and simplify the process.

For example, Japanese Patent Application Laid-Open No. 2016-32078 discloses an attachment device that attaches an adhesive film, which is an attachment material, to a workpiece, such as a wafer, which is an attachment target, by a vacuum lamination method using an elastic layer for attachment, such as a diaphragm. In this device, by attaching an adhesive film by an elastic layer under a depressurized condition, it is possible to conformally attach the adhesive film to follow the shape and uneven contours (which may be induced by bumps formed on the workspace) of the underlying attachment surface.

In the conventional attachment device, in order to increase the adhesiveness of the adhesive film, the workpiece is sometimes heated, for example, through a stage or the like. The adhesive film exhibits good adhesive properties as the adhesiveness increases when the workpiece is heated. Meanwhile, the elastic layer is heated by coming into contact with the heated workpiece or stage. Since the elastic layer is formed of an elastic material such as natural rubber or synthetic rubber that can be stretched, it may deteriorate and change the shape when heated. The elastic layer with changed shape has a problem in that the adhesive film's absorbability is reduced, making it impossible to absorb accurately or to determine the exact position of the workpiece.

In addition, there is a problem that when the adhesive film comes into contact with an elastic layer that has not been sufficiently cooled after heating, a reaction of the adhesive formed on the bonding surface is unintentionally initiated, resulting in poor bonding during bonding.

Accordingly, in order to solve the above problem, in the attachment device, there are cases where air is blown onto the elastic layer to cool it during the period from the time when the film is pressed until the subsequent adhesive film is absorbed. However, cooling by air has the problem of long cooling time and reduced productivity.

### SUMMARY OF THE INVENTION

An aspect of the present invention provides an apparatus for manufacturing a semiconductor device to reduce the above-mentioned problems, and specifically, provides a mounting device capable of reducing attachment defect by cooling an elastic layer without deteriorating productivity.

An embodiment of the inventive concept provides an apparatus for manufacturing a semiconductor device. The apparatus is configured to attach an adhesive film to an attachment surface of a workpiece under a depressurized condition. The apparatus comprises a chamber including a housing and a cover detachably coupled to the housing, and a stage accommodated in the chamber and having a holding chuck configured to secure the workpiece and a first heater configured to heat the workpiece. The housing has a discharge opening which is configured to depressurize an interior of the chamber. The cover comprises an elastic layer, a cover body, and a cooling part. The elastic layer is disposed at a lower surface of the cover body to face the holding chuck of the stage. The elastic layer is configured to secure the adhesive film. The elastic layer has a first surface configured to attach the adhesive film on the attachment surface of the workpiece. The elastic layer has a second surface which is facing away from the first surface. The lower surface of the cover body faces the second surface of the elastic layer. The cover body has a ventilation hole fluidly communicating with the second surface of the elastic layer. The cooling part is in contact with the elastic layer.

An embodiment of the inventive concept provides an apparatus for manufacturing a semiconductor device. The apparatus is configured to attach an adhesive film to an attachment surface of a workpiece. The apparatus comprises a chamber comprising a housing and a cover relatively movable with respect to the housing, and a stage accommodated in the chamber. The chamber has a processing space which is defined by contacting the cover with the housing. The processing space is configured to attach the adhesive film to the workpiece. The stage is configured to secure the workpiece, and to be relatively movable with respect to the cover. The cover comprises an elastic layer, a cover body, and a cooling part. The elastic layer is disposed at a lower surface of the cover body to face the stage. The elastic layer has a first surface configured to attach the adhesive film on the attachment surface of the workpiece. The elastic layer has a second surface which is facing away from the first surface. The elastic layer is configured to be deformed to follow a surface shape of the attachment surface of the workpiece. The elastic layer is configured to deform the adhesive film to follow a shape of the elastic layer. The lower surface faces the second surface of the elastic layer. The cover body has a ventilation hole fluidly communicating with the second surface of the elastic layer. The cooling part is disposed between the second surface of the elastic layer and the lower surface of the cover body. The cooling part is configured to cool the elastic layer.

An embodiment of the inventive concept provides an apparatus for manufacturing a semiconductor device. The apparatus is configured to attach an adhesive film to an attachment surface of a workpiece. The apparatus comprises a chamber comprising a housing having a discharge opening, and a cover relatively movable with respect to the housing, and a stage having a stage main body accommodated in the chamber, a holding chuck configured to secure the workpiece and a heater configured to heat the workpiece. The chamber has a processing space defined by contacting the cover with the housing. The processing space is configured to attach the adhesive film to the workpiece within the processing space under a depressurized condition. The processing space is configured to adjust the discharge opening to provide the depressurized condition. The stage is configured to be relatively movable with respect to the cover. The cover comprises an elastic layer, a cover body having a ventilation hole, and a cooler. The elastic layer is disposed at a lower surface of the cover body to face the holding chuck of the stage. The elastic layer has a first surface configured to secure the adhesive film. The elastic layer has a second surface which is facing away from the first surface. The elastic layer is configured to be deformed to follow a surface shape of the attachment surface of the workpiece. The elastic layer is configured to deform the adhesive film to follow a shape of the elastic layer. The elastic layer is configured to expand by introduction of gas through the ventilation hole and to contract by discharge of gas through the ventilation hole such that the adhesive film is deformed to follow the expansion or contraction of the elastic layer. The lower surface faces the second surface of the elastic layer. The cooler is disposed between the second surface of the elastic layer and the lower surface of the cover body. The cooler is in contact with the elastic layer and configured to cool the elastic layer.

An embodiment of the inventive concept provides a mounting device configured to attach an adhesive film to an attachment surface of a workpiece, the mounting device including a chamber in which a cover body and a housing are detachably configured, and configured to attach the adhesive film to the workpiece under a depressurized condition, and a stage accommodated in the chamber, and having a holding part configured to maintain the workpiece and a heating part configured to heat the workpiece, where the housing has a discharge opening for depressurizing an interior of the chamber, where the cover body comprises an elastic layer, a base portion, and a cooling part, wherein the elastic layer is disposed at a position facing the holding part of the stage, is formed of an elastic member capable of maintaining the adhesive film, and has a first surface capable of attaching the adhesive film on an attachment surface of the workpiece and a second surface on an opposite side to the first surface, wherein the base portion has an A-surface facing the second surface of the elastic layer and a ventilation hole communicating with at least a surface of the A-surface and an exterior of the chamber, and where the cooling part is in contact with the elastic layer to cool the elastic layer.

An embodiment of the inventive concept provides the mounting device of the above, where the cooling part is at least one thermoelectric element disposed between the second surface and the A-surface.

An embodiment of the inventive concept provides the mounting device of the above, where the cooling part is a cooling plate disposed on the A-surface and capable of flowing a refrigerant.

An embodiment of the inventive concept provides the mounting device of the above, where the cooling part is a refrigerant fluid line disposed in an interior of the elastic layer.

An embodiment of the inventive concept provides the mounting device of the above, where the elastic layer has an auxiliary heating part that auxiliary heats the adhesive film.

An embodiment of the inventive concept provides the mounting device of the above, where the auxiliary heating part is a heater having a wiring made of a conductive resin formed on the first surface of the elastic layer, and heats by applying voltage with the wiring resistance.

An embodiment of the inventive concept provides the mounting device of the above, where the heater is disposed in a plurality of heating regions partitioned from the first surface of the elastic layer.

An embodiment of the inventive concept provides the mounting device of the above, where the adhesive film is a resin film having an insulating property.

An embodiment of the inventive concept provides the mounting device of the above, where the elastic layer is a diaphragm formed of silicon rubber.

An embodiment of the inventive concept provides the mounting device of the above, where an adsorption surface having a plurality of regions having different adsorption forces is disposed on the first surface of the elastic layer.

An embodiment of the inventive concept provides the mounting device of the above, where, on the adsorption surface, the regions having different adsorption forces are formed according to a difference of a surface roughness of the first surface.

An embodiment of the inventive concept provides the mounting device of the above, where, on the adsorption surface, the regions having different adsorption forces are formed according to a difference of friction coefficient of a material forming the first surface.

An embodiment of the inventive concept provides the mounting device of the above, provided with a controller that executes an adsorption process of adsorbing the adhesive film on the first surface of the elastic layer, a processing space forming process of forming a processing space as the chamber by combining the cover body and the housing, an attaching process of expanding the elastic layer by at least one of a processing of depressurizing the interior of the chamber or a processing of introducing the gas from the ventilation hole to the interior of the chamber, and attaching the adhesive film to the workpiece mounted on the stage, and a cooling process of cooling the elastic layer by the cooling part.

According to the present invention, it is possible to prevent attachment defect by cooling an elastic layer without reducing productivity.

### BRIEF DESCRIPTION OF THE DRAWINGS

FIG. 1 is a schematic cross-sectional view of a mounting device according to a first embodiment of the present invention.

FIG. 2A is a schematic cross-sectional view showing a cooling part of a mounting device according to an example of the first embodiment.

FIG. 2B is a schematic cross-sectional view showing a cooling part of a mounting device according to an example of the first embodiment.

FIG. 2C is a schematic cross-sectional view showing a cooling part of a mounting device according to an example of the first embodiment.

FIG. 3 is a flowchart showing an operation of a mounting device according to the first embodiment.

FIG. 4A is a schematic cross-sectional view showing an operation of a mounting device according to the first embodiment.

FIG. 4B is a schematic cross-sectional view showing an operation of a mounting device according to the first embodiment.

FIG. 4C is a schematic cross-sectional view showing an operation of a mounting device according to the first embodiment.

FIG. 4D is a schematic cross-sectional view showing an operation of a mounting device according to the first embodiment.

FIG. 4E is a schematic cross-sectional view showing an operation of a mounting device according to the first embodiment.

FIG. 4F is a schematic cross-sectional view showing an operation of a mounting device according to the first embodiment.

FIG. 4G is a schematic cross-sectional view showing an operation of a mounting device according to the first embodiment.

FIG. 4H is a schematic cross-sectional view showing an operation of a mounting device according to the first embodiment.

FIG. 5 is a schematic cross-sectional view of a mounting device according to a second embodiment of the present invention.

FIG. 6 is a schematic diagram in a planar view of a cooling plate that function as a cooling part of a mounting device according to an example of the second embodiment.

FIG. 7A is a schematic cross-sectional view showing an operation of a mounting device according to the second embodiment.

FIG. 7B is a schematic cross-sectional view showing an operation of a mounting device according to the second embodiment.

FIG. 7C is a schematic cross-sectional view showing an operation of a mounting device according to the second embodiment.

FIG. 7D is a schematic cross-sectional view showing an operation of a mounting device according to the second embodiment.

FIG. 7E is a schematic cross-sectional view showing an operation of a mounting device according to the second embodiment.

FIG. 7F is a schematic cross-sectional view showing an operation of a mounting device according to the second embodiment.

FIG. 7G is a schematic cross-sectional view showing an operation of a mounting device according to the second embodiment.

FIG. 7H is a schematic cross-sectional view showing an operation of a mounting device according to the second embodiment.

FIG. 8 is a schematic cross-sectional view of a mounting device according to a third embodiment of the present invention.

FIG. 9A is a schematic diagram of a planar view of an elastic layer in which a refrigerant fluid line functioning as a cooling part of a mounting device according to an example of the third embodiment is formed, when viewed from a second surface side.

FIG. 9B is a partial cross-sectional view of an elastic layer in which a refrigerant fluid line is formed, according to an example embodiment.

FIG. 10A is a schematic cross-sectional view showing an operation of a mounting device according to the third embodiment.

FIG. 10B is a schematic cross-sectional view showing an operation of a mounting device according to the third embodiment.

FIG. 10C is a schematic cross-sectional view showing an operation of a mounting device according to the third embodiment.

FIG. 10D is a schematic cross-sectional view showing an operation of a mounting device according to the third embodiment.

FIG. 10E is a schematic cross-sectional view showing an operation of a mounting device according to the third embodiment.

FIG. 10F is a schematic cross-sectional view showing an operation of a mounting device according to the third embodiment.

FIG. 10G is a schematic cross-sectional view showing an operation of a mounting device according to the third embodiment.

FIG. 10H is a schematic cross-sectional view showing an operation of a mounting device according to the third embodiment.

FIG. 11 is a schematic diagram of an auxiliary heating part provided as a first modified configuration of a mounting device according to an example embodiment of the present invention.

FIG. 12 is a schematic view showing an arrangement example of heating regions of an auxiliary heating part of the first modified configuration.

FIG. 13 is a schematic view showing an example of forming the adsorption surface provided as a second modified configuration of a mounting device according to an example embodiment of the present invention.

FIG. 14 is a schematic view showing another example of forming an adsorption surface of the second modified example.

### DETAILED DESCRIPTION OF THE EMBODIMENTS

Hereinafter, embodiments of the present invention will be described in detail with reference to the accompanying drawings. In the drawings below, the same reference numerals represent the same components, and the size of each component may be exaggerated for clarity and convenience of description. In addition, the embodiments described below are merely exemplary, and various modifications are possible from such embodiments.

In the following, the terms “upper” or “above” may include not only being directly above in contact, but also being above in a non-contacting manner. Likewise, the terms “lower” or “below” may include not only being directly below in contact, but also being below in non-contact.

A singular expression includes a plural expression unless the context clearly indicates that it is singular. Items described in the singular herein may be provided in plural, as can be seen, for example, in the drawings. Thus, the description of a single item that is provided in plural should be understood to be applicable to the remaining plurality of items unless context indicates otherwise.

Additionally, when a part is said to “include,” “provided with,” or “have” a component, it means that, unless otherwise specifically stated, it may include other components, rather than excluding other components. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

For the steps that constitute a method, the sequence may be explicitly stated, or, if there is no contrary statement, the steps are executed in the appropriate sequence. It is not necessarily limited to the sequence in which the above steps are described. Any use of examples or exemplary terms is intended solely to illustrate technical ideas and is not intended to limit the scope of the invention, unless otherwise limited by the scope of the claims.

Also, in the description below, when describing by adding ordinal numbers such as “first” and “second,” unless specifically stated otherwise, it is used for convenience and does not stipulate any sequence. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim.

A mounting device 100 according to a first embodiment of the present invention will be described. The mounting device may be or include an apparatus for attaching a film to a workpiece and may be used as an apparatus for manufacturing a semiconductor device.

The mounting device 100 of the first embodiment is an apparatus for attaching a workpiece W formed of various wafers such as a glass substrate, a resin substrate, and a ceramic substrate, which are processed to a semiconductor chip, a substrate, or the like, to an adhesive film F having an insulating property. In an embodiment, the mounting device 100 may be an apparatus for attaching an adhesive film F to a workpiece W. As an example, the workpiece W may be a wafer attached to a dicing tape and secured to a dicing frame. The adhesive film F may be a resin film that has an insulating property, and has adhesiveness capable of being attached to the workpiece W. An adhesiveness of the adhesive film F may be raised by heating.

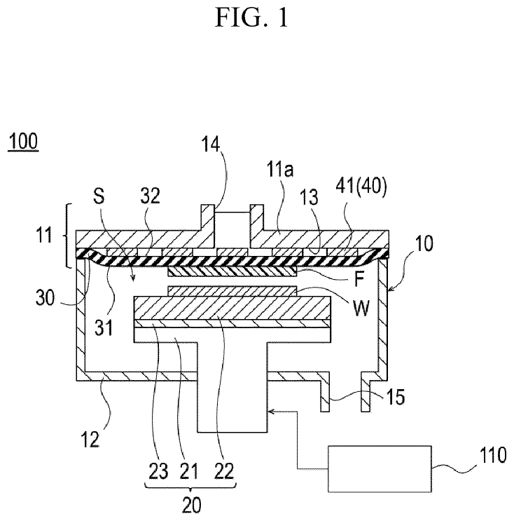

As shown in FIG. 1, the mounting device 100 is configured to include a chamber 10 that forms a processing space S for attaching the adhesive film F to the workpiece W under a depressurized condition, and a stage 20 that is accommodated within the chamber 10 and relatively movable with respect to a cover 11 (e.g., the two components are movable relative to one another). The mounting device 100 is provided with a controller 110 shown in FIG. 1, and the driving control of each part is performed according to a predetermined driving program. The controller 110 may be a computer or a processor, such as a DSP, an FPGA, a CPU, a GPU, a microprocessor, etc.

The chamber 10 is configured so that the cover 11 and a housing 12 can move relatively close to each other and away from each other. The chamber 10 may form the processing space S by tightly contacting the cover 11 and the housing 12. In the chamber 10, the pressure within the processing space S is adjustable by a vacuum pump (not shown) or the like from (through) a discharge opening 15 of the housing 12. The adhesive film F is attached to the workpiece W under a depressurized condition in which the interior of the processing space S is depressurized to a predetermined pressure.

The cover 11 has a base portion (cover body) 11a and an elastic layer 30 installed in the base portion 11a and maintaining the adhesive film F. The base portion 11a has an A-surface 13 facing a second surface 32 of the elastic layer 30. The base portion 11a has a ventilation hole 14 communicating with at least a surface of the A-surface 13 and an exterior of the chamber 10. The cover 11 is disposed at a position facing an electrostatic chuck 22 (holding part) of the stage 20.

For example, the cover 11 may have a cover body 11a and an elastic layer 30 installed in the cover body 11a. The elastic layer 30 may be configured to secure (hold) the adhesive film F. The cover body 11a may have an A-surface 13 facing a second surface 32 of the elastic layer 30. The A-surface 13 may be a lower surface of the cover body 11a. The cover body 11a may have a ventilation hole 14 fluidly communicating with the A-surface 13 and an exterior of the chamber 10. For example, the ventilation hole 14 may fluidly communicate with the second surface 32 of the elastic layer 30 and an air compressor such that an air can flow therebetween. The cover 11 may be disposed at a position facing an electrostatic chuck 22 (e.g., holding part or holding chuck) of the stage 20.

The cover 11 is connected to a moving device (not shown), and configured to be movable along a first direction (vertical direction in FIG. 1) toward and away from the housing 12, and a second direction (left-and-right direction or the like in FIG. 1) intersecting the first direction.

The elastic layer 30 is formed of an elastic member (e.g., formed of elastic material) having an elasticity. The elastic layer 30 may be formed of, for example, natural rubber, synthetic rubber such as silicon rubber, or the like, and capable of maintaining (securing) the adhesive film F. In one embodiment, the elastic layer 30 is formed of silicone rubber considering heat resistance, durability, insulating property, adhesiveness to the adhesive film F, or the like.

The elastic layer 30 has a first surface 31 capable of attaching the adhesive film F on an attachment surface Wa of the workpiece W, and the second surface 32 opposite to (facing away from) the first surface 31. Since the elastic layer 30 is formed of a stretchable elastic member, it can be deformed to follow a surface shape of the attachment surface Wa of the workpiece W. Since the adhesive film F can be deformed to follow a shape of the elastic layer 30, it may be attached without forming a void on the attachment surface Wa of the workpiece W.

The elastic layer 30 expands when air is introduced into a space between the base portion 11a and the elastic layer 30 through the ventilation hole 14 of the base portion 11a. Accordingly, the first surface 31 of the elastic layer 30 protrudes toward the stage 20. The elastic layer 30 contracts when the air within the space is discharged from the ventilation hole 14. Accordingly, the second surface 32 of the elastic layer 30 moves toward the A-surface 13 of the base portion 11a. As the elastic layer 30 expands, attachment of the adhesive film F to the workpiece W may be performed. The elastic layer 30 can be accommodated by contracting so as not to interfere with the transition to the subsequent process. For example, by the contracting, the elastic layer 30 may be returning to its original shape and position. In addition, the elastic layer 30 may expand by at least one of the processing of depressurizing the interior of the chamber 10 and the processing of introducing gas from the ventilation hole 14 into the interior of the chamber 10.

The stage 20 is configured to include a stage main body 21, the electrostatic chuck 22 that functions as a holding part for maintaining the workpiece W, and a heating part (heater) 23 that heats the workpiece W. The stage 20 is configured so that the stage main body 21 can move relatively close to and away from the cover 11.

The heating part 23 heats the workpiece W. The heating part 23 may be a configuration capable of heating the workpiece W to a predetermined temperature (e.g., about 100° C.) directly or indirectly through the electrostatic chuck 22, or the like. As shown in FIG. 1, the heating part 23 is built into the stage 20, and indirectly heats the workpiece W by heating the electrostatic chuck 22. For example, the heating part 23 may be embedded in the stage 20, and indirectly heats the workpiece W by heating the electrostatic chuck 22.

For example, the heater 23 may be one of a resistance heater (electric heater) using a metal conductor or a thin-film conductor which act as a heating element when current flows therethrough, an inductive heater using electromagnetic induction to heat a conductive material (e.g., the chuck itself), a thermal conduction heater using heat transfer from a heated source to the chuck by heat transfer medium, a plasma heater using the energy from plasma source, an infrared (IR) heater using radiant energy, a Peltier (thermoelectric) heater using the Peltier effect, and so on.

The mounting device 100 has a cooling part 40 that cools the elastic layer 30.

The cooling part 40 is disposed between the second surface 32 of the elastic layer 30 and the A-surface 13 of the base portion 11a, and cools the elastic layer 30. The cooling part 40 may be a cooler configured including a thermoelectric element (thermoelectric device) 41 such as a plurality of Peltier elements (Peltier devices). For example, the cooler 40 may be one of a water-cooled chiller, a refrigerant-based cooler using a refrigerant (such as Freon or ammonia), other liquid cooling system using deionized water or specialized coolants, an air-cooled heat exchanger transferring air over the surface of the chuck or other parts, a cryogenic cooler using liquefied gases such as nitrogen or helium, a liquid nitrogen (LN2) cooler, a phase change cooler using materials that absorb heat during the process of transitioning from solid to liquid (or vice versa), and so on.

After the adhesive film F is attached to the workpiece W by the elastic layer 30, the cooling part 40 operates for a predetermined time to cool the elastic layer 30, until moving to bring the subsequent adhesive film F. Since the cooling part 40 cools the elastic layer 30 by being in contact, it can efficiently cool the elastic layer 30 in a short period of time without taking a long cooling time like air injection.

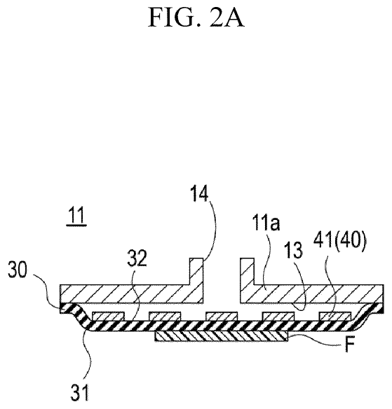

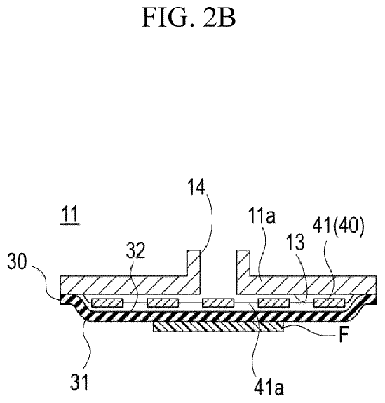

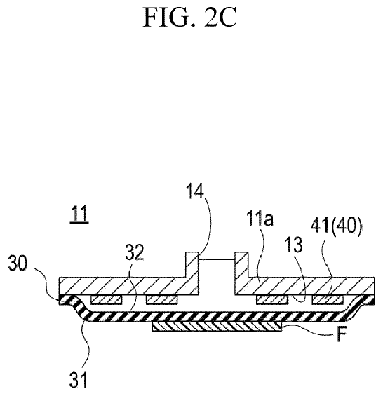

FIG. 2A to FIG. 2C illustrate the arrangement form of the cooling part 40. As shown in FIG. 2A, the cooling part 40 may be formed by disposing a plurality of thermoelectric elements 41 on the second surface 32 of the elastic layer 30. As shown in FIG. 2B, the cooling part 40 may be disposed between the second surface 32 of the elastic layer 30 and the A-surface 13 of the base portion 11a. The cooling part 40 shown in FIG. 2B may be configured, for example, by disposing the plurality of thermoelectric elements 41 on a conductive film 41a. As shown in FIG. 2C, the cooling part 40 may be formed by disposing the plurality of thermoelectric elements 41 on the A-surface 13 of the base portion 11a.

In each of the examples shown in FIG. 2A to FIG. 2C, in the viewpoint of preventing partial degradation by suppressing non-uniformity of temperature at the time of cooling, it is preferable to dispose of the cooling part 40 such that the entire elastic layer 30 may be uniformly cooled. In addition, it is preferable that the cooling part 40 is disposed so as not to affect the elastic deformation of the elastic layer 30.

Subsequently, an operation of the mounting device 100 according to the first embodiment will be described. In addition, the series of operations shown below is merely an example, and other actions (or additional operations) may be added between respective actions (operations) as needed. In addition, the operation represented below may have its operation sequence altered, within a range that does not depart from the main concept of the present invention. For example, the operation sequence represented below may be modified, as long as such modifications do not deviate or depart from the spirit and scope of the present invention.

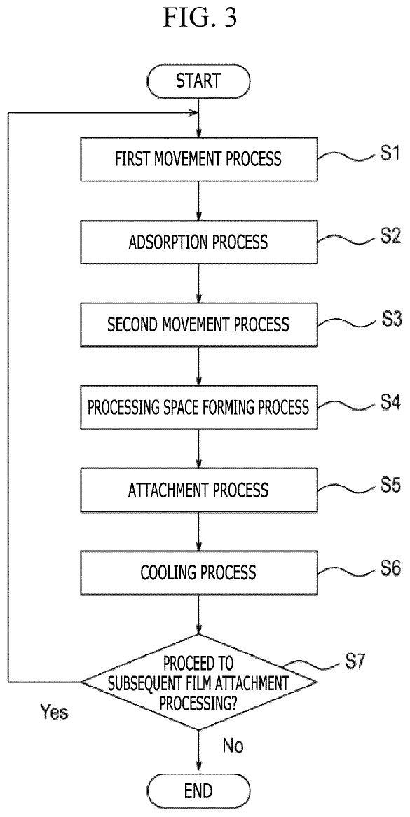

FIG. 3 is a flowchart showing an operation of a mounting device according to the first embodiment. The flowchart may illustrate a process for manufacturing a semiconductor device using the mounting device according to the first embodiment. As shown in FIG. 3, the manufacturing process may include a film attachment processing by using the mounting device 100. The film attachment processing may include a first moving process S1, an adsorption process S2, a second moving process S3, a processing space forming process S4, an attaching process S5, and a cooling process S6. In the mounting device 100, each processing (process step) is performed under the control of the controller 110.

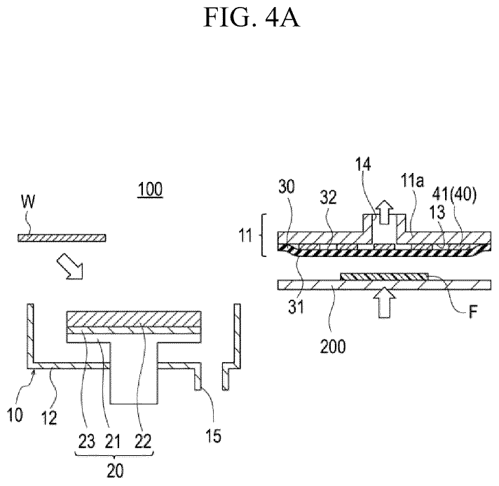

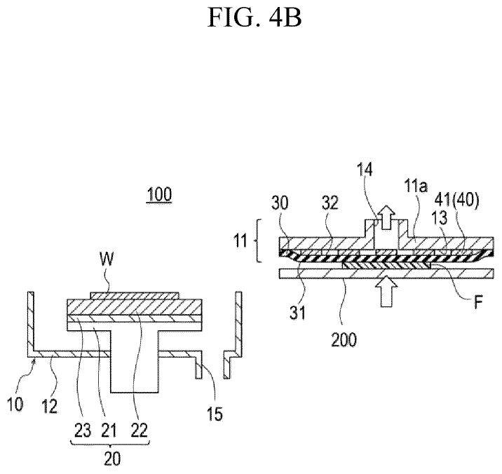

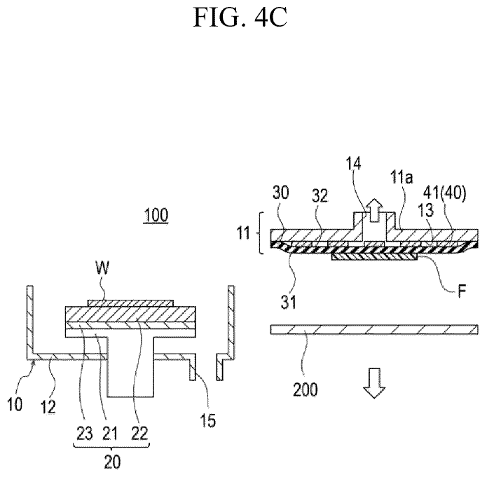

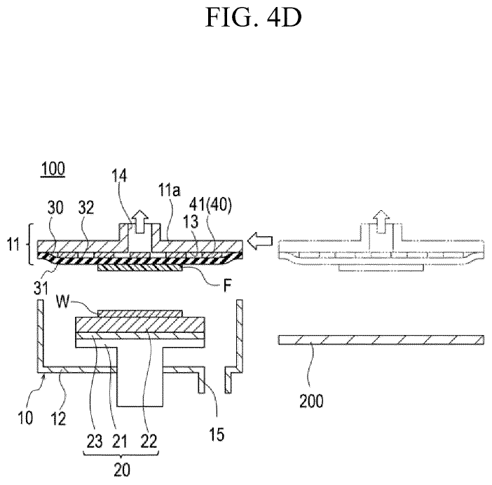

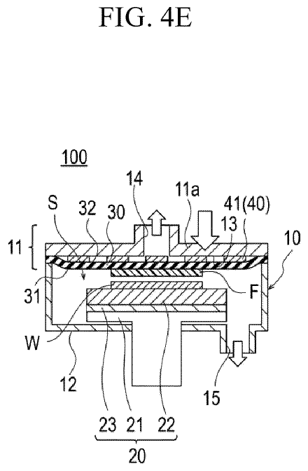

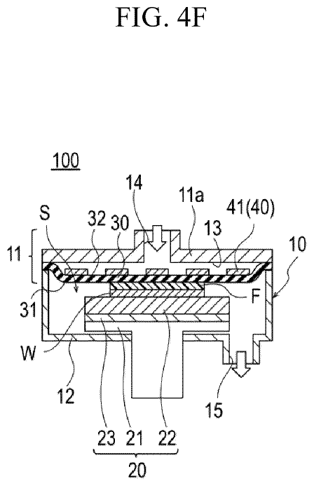

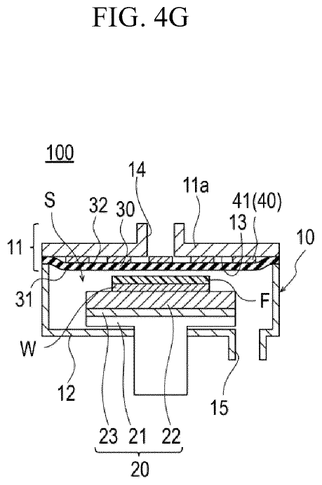

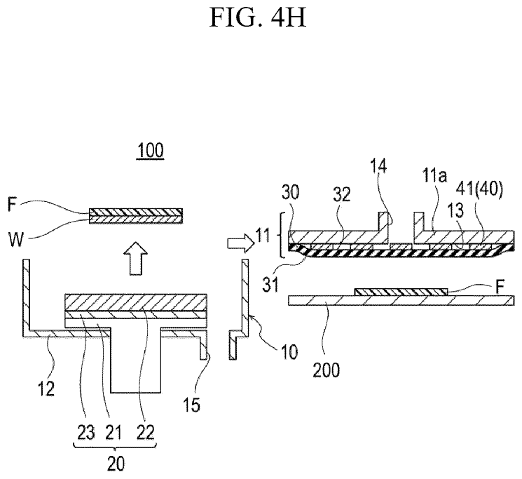

As shown in FIG. 4A, the mounting device 100 performs the first moving process S1. The mounting device 100 may operate to mount the workpiece W on the electrostatic chuck 22, and the cover 11 may move to bring the adhesive film F mounted on a mounting stand 200. The mounting device 100 may operate to contract the elastic layer 30 by drawing (removing) air from (through) the ventilation hole 14.

As shown in FIG. 4B, the mounting device 100 performs the adsorption process S2. The mounting stand 200 may be moved up toward the cover 11. By pressurizing the first surface 31 of the elastic layer 30 on the adhesive film F, the cover 11 may adsorb (secure) the adhesive film F to the first surface 31.

As shown in FIG. 4C, the mounting device 100 performs the second moving process S3. After receiving the adhesive film F from the mounting stand 200, the cover 11 may be raised (moved upward) from the mounting stand 200. Thereafter, as shown in FIG. 4D, the cover 11 may move back to an upper side of the housing 12.

As shown in FIG. 4A to FIG. 4C, the mounting stand 200 moves up and down, at the time of transferring the adhesive film F.

As shown in FIG. 4E, the mounting device 100 performs the processing space forming process S4. The cover 11 may be moved relatively with respect to the housing 12, and may be in tight contact with the housing 12, thereby forming (providing) a processing space S. When (and/or after) the processing space S formed, the mounting device 100 discharges the interior air from the processing space S through the discharge opening 15, to depressurize the processing space S to the predetermined pressure.

As shown in FIG. 4F, the mounting device 100 performs the attaching process S5, and expands the elastic layer 30 by introducing air from the ventilation hole 14 into the interior of the cover 11. In addition, the mounting device 100 raises the stage 20 toward the cover 11 in accordance with the expansion of the elastic layer 30. In an embodiment, the expanding of the elastic layer 30 and the raising the stage 20 toward the cover 11 may occur simultaneously. In another embodiment, the expanding of the elastic layer 30 and the raising the stage 20 toward the cover 11 may occur right after each other. At this time, the adhesive film F becomes highly adhesive to the heated workpiece W by being in contact with the attachment surface Wa of the workpiece W. The adhesive film F may be attached to the attachment surface Wa of the workpiece W, and detached from the first surface 31 of the elastic layer 30. For example, the adhesive film F may be detached from the first surface 31 by contraction of the elastic layer 30. During the adhesive film F being attached to the attachment surface Wa of the workpiece W, the elastic layer 30 may be deformed so that a void may not be formed to follow a surface shape of the attachment surface Wa of the workpiece W.

As shown in FIG. 4G, the mounting device 100 performs the cooling process S6. When (and/or after) the attachment of the adhesive film F is completed, the chamber 10 is open (exposed) to the atmosphere and the air in the interior of the cover 11 is discharged from (through) the ventilation hole 14, thereby contracting the elastic layer 30. In addition, simultaneously with the opening to the atmosphere, the mounting device 100 drives the cooling part 40 to cool the elastic layer 30. The cooling part 40 may cool the entire elastic layer from the second surface 32 of the elastic layer 30 by driving (using) the thermoelectric element 41. For example, during the cooling, the thermoelectric element 41, which has high cooling efficiency, may be in contact with the second surface 32 of the elastic layer 30. Accordingly, the time to cool the elastic layer 30 may be significantly reduced.

Thereafter, as shown in FIG. 4H, the mounting device 100 moves the cover 11 toward the mounting stand 200, in order to move to bring (pick up) the subsequent adhesive film F. Since the elastic layer 30 has been sufficiently cooled by the cooling part 40, when the subsequent adhesive film F is adhered to the first surface 31, an unintentional increase of adhesiveness is prevented. Accordingly, the elastic layer 30 may be under an appropriate condition to suppress any unintentional problems.

Thereafter, the mounting device 100 repeats the operation described with reference to FIG. 4A to FIG. 4H, to attach the adhesive film F to the workpiece W. For example, at a process step S7, it may be determined whether a subsequent film attachment processing is performed. When proceeding to the subsequent film attachment processing (S7—Yes), the mounting device 100 returns back to the process step S1, to perform the subsequent film attachment processing. In addition, when the subsequent film attachment processing does not proceed (S7—No), the manufacturing process may be terminated.

Subsequently, a mounting device 100A according to a second embodiment of the present invention will be described. As for the mounting device 100A according to a second embodiment described hereinafter, the same reference symbol will be assigned to the same configuration as the above-described embodiment, and their descriptions will be omitted. In addition, for points not specifically mentioned, the configuration may be the same as the above-described embodiment.

The mounting device 100A according to a second embodiment of the present invention has a different example of the cooling part from the above-described example.

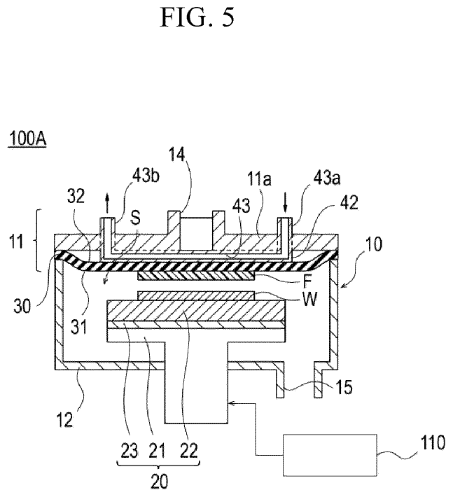

As shown in FIG. 5, in the mounting device 100A of the second embodiment, the cooling part is composed of a cooling plate 42.

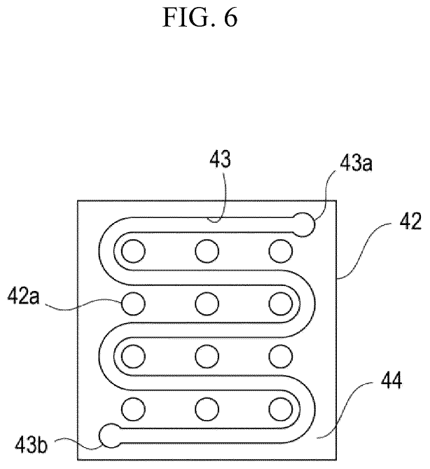

As shown in FIG. 6, the cooling plate 42 has a fluid line 43 through which the refrigerant circulates, a first flow portion 43a disposed in a first end portion of the fluid line 43 (through which the refrigerant flows in), a second flow portion 43b disposed in a second end portion of the fluid line 43 (through which the refrigerant flows out), and a plate 44 in which the fluid line 43 is formed. In the plate 44, a plurality of air holes 42a for circulating (and/or control) air for contracting and expanding the elastic layer 30, in fluid communication with the ventilation hole 14, are formed.

The fluid line 43 may be formed over the entire plate 44. The fluid line may be arranged to uniformly and efficiently cool the entire area of the plate 44. For example, the fluid line 43 may be arranged to follow a winding path shape in a plan view, showing a series of regular, evenly spaced curves and bends throughout its length. A shape of the fluid line 43 is not limited to the winding shape as shown in FIG. 6, and may have a path of other shape that can efficiently cool the entire plate 44. The plate 44 may have a contactable area over at least the entire second surface 32 of the elastic layer 30. For example, the plate 44 may be formed of a material, which is expandable and contractible while the plate 44 is in contact with the elastic layer 30. Accordingly, the cooling plate 42 may uniformly cool the entire elastic layer 30.

The cooling plate 42 is disposed on the A-surface 13 of the base portion 11a. The elastic layer 30 is cooled by being in contact with the cooling plate 42, when contracted after attachment of the adhesive film F to the workpiece W.

As a refrigerant (cooling fluid) circulating through the fluid line 43 of the cooling plate 42, water (adjusted to the predetermined temperature) can preferably be used from the viewpoint of handleability. However, the refrigerant may be a heat medium (fluid capable of transferring heat) other than water.

Subsequently, an operation of the mounting device 100A according to the second embodiment will be described. In addition, the series of operations shown below is merely an example, and other actions may be added between respective actions as needed. In addition, the operation represented below may be modified, as long as such modifications do not depart from the main concept of the present invention.

The mounting device 100A according to the second embodiment performs the same processing as the mounting device 100 of the first embodiment shown in FIG. 3, in performing the film attachment processing. However, the cooling method of the cooling process S6 may be different from that of the mounting device 100.

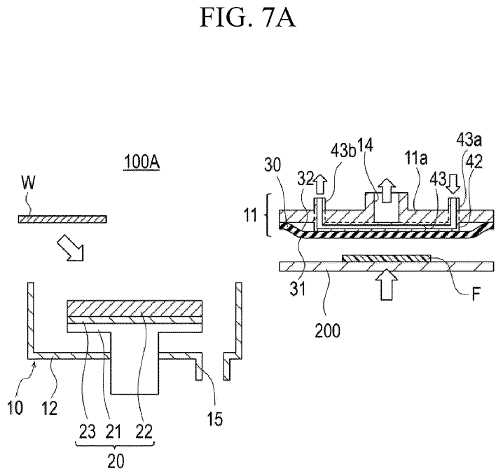

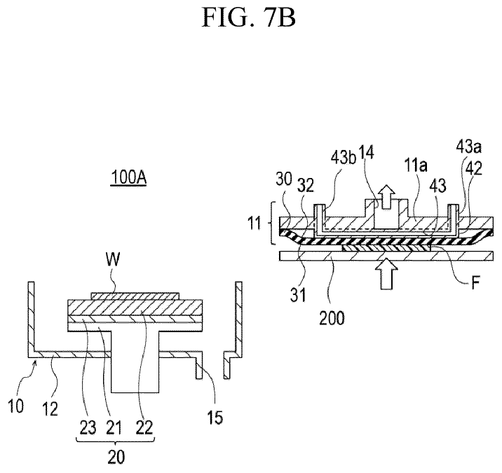

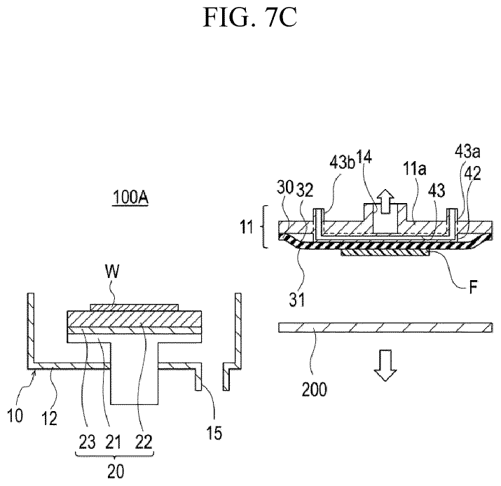

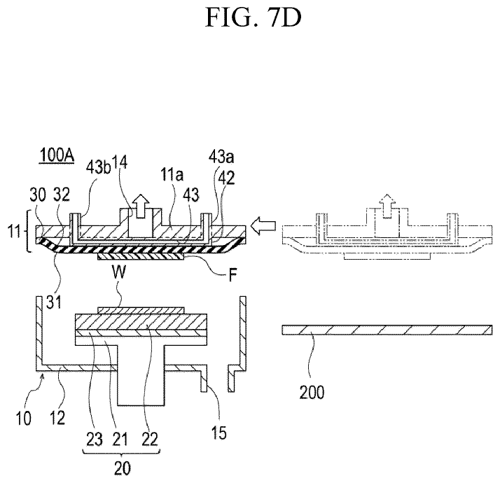

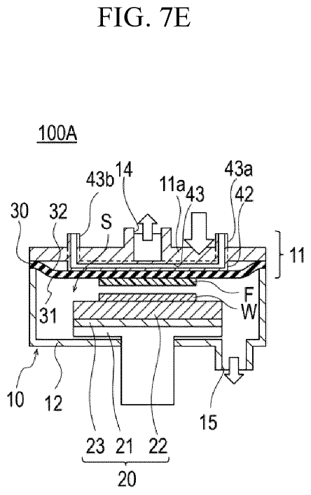

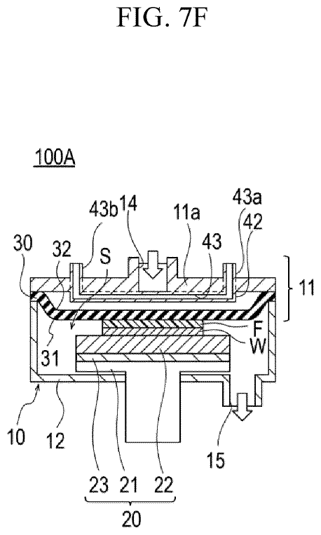

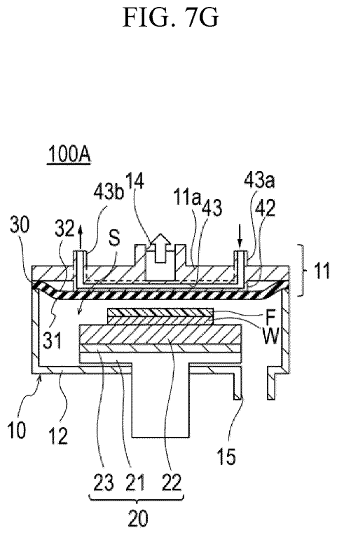

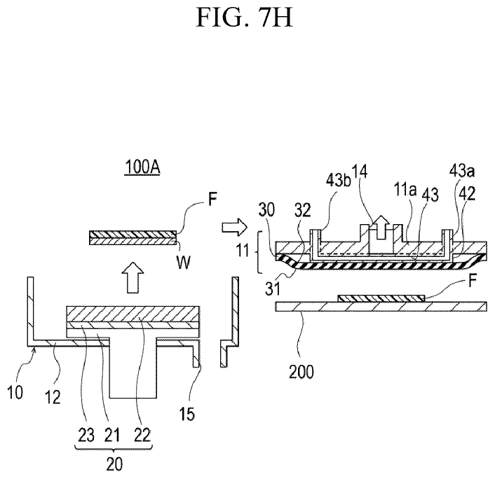

Referring to FIGS. 7A to 7H, process steps S1 to S7 of the flowchart in FIG. 3 may be performed in substantially the same manner as those described with reference to FIGS. 4A to 4H. Accordingly, repetitive descriptions may be briefly explained or omitted for conciseness, and following description may be focused on the difference therebetween.

As shown in FIG. 7A, the mounting device 100A performs the first moving process S1, mounts the workpiece W on the electrostatic chuck 22, and moves the cover 11 to move to bring the adhesive film F mounted on the mounting stand 200. In addition, the mounting device 100A initiates the operation of the cooling part 42. The mounting device 100 contracts the elastic layer 30 by drawing air from (removing air through) the ventilation hole 14, and cools the elastic layer 30 by bringing it in contact with the cooling plate 42. While cooling, the heat medium may flow in through the first flow portion 43a, and may flow out through the second flow portion 43b.

As shown in FIG. 7B, the mounting device 100A performs the adsorption process S2, and pressurizes the first surface 31 of the elastic layer 30 on the adhesive film F, to adhere the adhesive film F to the first surface 31. As shown in FIG. 7C, the mounting device 100A performs the second moving process S3, raises the cover 11 having received the adhesive film F from the mounting stand 200, and as shown in FIG. 7D, returns it to an upper side of the housing 12. As shown in FIG. 7A to FIG. 7C, the mounting stand 200 moves up and down, at the time of transferring the adhesive film F.

As shown in FIG. 7E, the mounting device 100A performs the processing space forming process S4, relatively moves the cover 11 with respect to the housing 12, and forms the processing space S by being in tight contact with the housing 12. When the processing space S formed, the mounting device 100A discharges the interior air within the processing space S through the discharge opening 15, to depressurize the processing space S to the predetermined pressure.

As shown in FIG. 7F, the mounting device 100A performs the attaching process S5, and expands the elastic layer 30 by introducing air from the ventilation hole 14. In addition, the mounting device 100A raises the stage 20 toward the cover 11 in accordance with the expansion of the elastic layer 30. At this time, the adhesive film F becomes highly adhesive to the heated workpiece W by being in contact, and is thus attached to the attachment surface Wa of the workpiece W from the first surface 31 of the elastic layer 30. In addition, the adhesive film F is attached to the attachment surface Wa of the workpiece W while following the deformation of the elastic layer 30, so that void is not formed.

As shown in FIG. 7G, the mounting device 100A performs the cooling process S6, and when (and/or after) the attachment of the adhesive film F is completed, the chamber 10 is opened to the atmosphere and the air in the interior of the cover 11 is discharged from the ventilation hole 14, thereby contracting the elastic layer 30. In addition, simultaneously with the opening to the atmosphere, the mounting device 100A drives (controls) the cooling part 42 to cool the elastic layer 30. The cooling part 42 may be configured to conduct the refrigerant through the fluid line 43. The elastic layer 30 is in contact with the cooling plate 42 provided with the fluid line 43 for circulating the refrigerant, and the entire elastic layer may be cooled from the second surface 32 of the elastic layer 30. For example, during the cooling, the cooling plate 42 may be in contact with the second surface 32 of the elastic layer 30. Accordingly, the time to cool the elastic layer 30 may be significantly reduced. Thereafter, as shown in FIG. 7H, the mounting device 100A moves the cover 11, in order to move to bring the subsequent adhesive film F. Since the elastic layer 30 has been cooled by the cooling part 42, when the adhesive film F is adhered to the first surface 31, an unintentional increase of adhesiveness is prevented.

Thereafter, the mounting device 100A repeats the operation shown in FIG. 7A to FIG. 7H, to attach the adhesive film F to the workpiece W. That is, the mounting device 100A determines, at S7, whether a subsequent film attachment processing may be performed. When proceeding to the subsequent film attachment processing (S7—Yes), the mounting device 100A returns back to S1, to perform the subsequent film attachment processing. In addition, when the subsequent film attachment processing is not proceeded, i.e., the processing is not performed (S7-No), the processing is terminated.

Subsequently, a mounting device 100B according to a third embodiment of the present invention will be described. As for the mounting device 1001B according to a third embodiment described hereinafter, the same reference symbol will be assigned to the same configuration as the above-described embodiment, and their descriptions will be omitted. In addition, for points not specifically mentioned, the configuration may be the same as the above-described embodiment.

The mounting device 100B according to the third embodiment of the present invention has a different example of the cooling part from the above-described example.

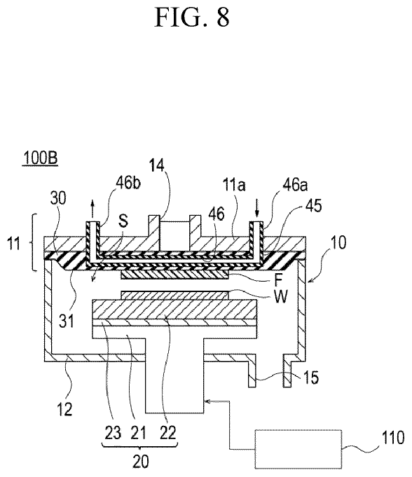

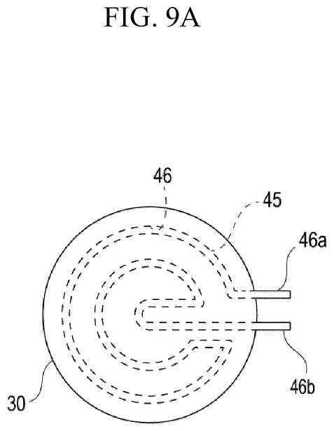

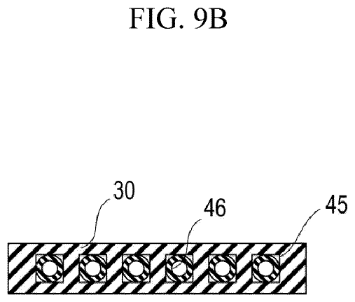

Referring to FIG. 8, 9A and FIG. 9B, a mounting device 100B may include a refrigerant fluid line 46 as a cooler. As shown in FIG. 8, in the mounting device 100B, the cooling part is composed of the refrigerant fluid line 46 formed on the elastic layer 30.

The refrigerant fluid line 46 may be a fluid line through which the refrigerant circulates, a first flow portion 46a disposed in a first end portion of the fluid line 46 (through which the refrigerant flows in), and a second flow portion 46b disposed in a second end portion of the fluid line 46 (through which the refrigerant flows out).

The refrigerant fluid line 46 may cool the entire surface of the elastic layer 30. Accordingly, as shown in FIG. 9A and FIG. 9B, the fluid line 46 may be formed such that the first flow portion 46a and the second flow portion 46b may fluidly communicate with each other. The first flow portion 46a and the second flow portion 46b do not break at once across the elastic layer 30. For example, the fluid line 46 may be arranged to form a single fluid path. As an example, the refrigerant fluid line 46 may be disposed by inserting it into a groove 45 formed in advance within the elastic layer 30. In some embodiments, the refrigerant fluid line 46 may be attached to the elastic layer 30 by fixing it using an adhesive or the like. In some embodiments, the refrigerant fluid line 46 may be surrounded by the elastic layer 30 without forming the groove 45 or the like, such that it may not be peeled off from the elastic layer 30.

The refrigerant fluid line 46 is not limited to the form shown in FIG. 9A and FIG. 9B. The refrigerant fluid line 46 may be one fluid line extending around the elastic layer 30. The refrigerant fluid line 46 may be arranged to form a single fluid passage extending around a substantially entire portion of the elastic layer 30. In addition, the refrigerant fluid line 46 may not be exposed to upper and lower surfaces of the elastic layer 30 such that it does not interfere with the attachment processing of the adhesive film F.

The refrigerant fluid line 46 may be formed in an interior of the elastic layer 30. In this case, the refrigerant fluid line 46 may be formed, for example, by configuring the elastic layer 30 by a pair of elastic layer members, and interposing the fluid line 46 between the elastic layer members. In addition, the refrigerant fluid line 46 may be formed by forming a recess portion to be the fluid line 46 in the interior of the elastic layer 30. For example, the refrigerant fluid line 46 may be formed in an interior of the elastic layer 30. In some embodiments, the groove 45 may be configured to have a pair of elastic layer members, and between the pair of elastic layer members, the fluid line 46 may be interposed. The groove 45 may accommodate the fluid line 46 in the interior of the elastic layer 30.

Subsequently, an operation of the mounting device 100B according to the third embodiment will be described. In addition, the series of operations shown below is merely an example, and other actions may be added between respective actions as needed. In addition, the operation sequence represented below may be modified, as long as such modifications do not deviate or depart from the spirit and concept of the present invention.

The mounting device 100B according to the third embodiment performs the same processing as the mounting device 100 of the first embodiment shown in FIG. 3, in performing the film attachment processing. However, the cooling method of the cooling process S6 may be different from that of the mounting device 100.

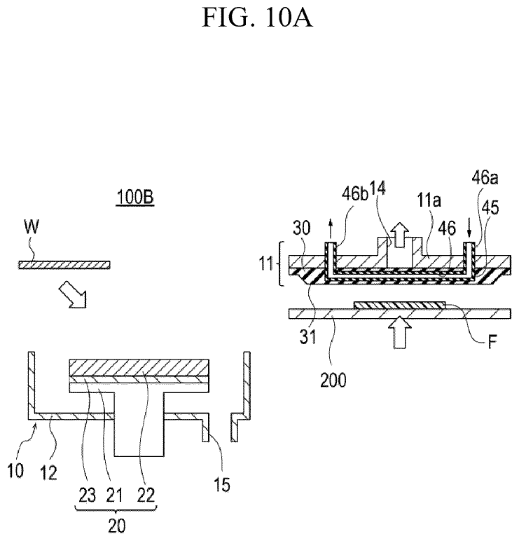

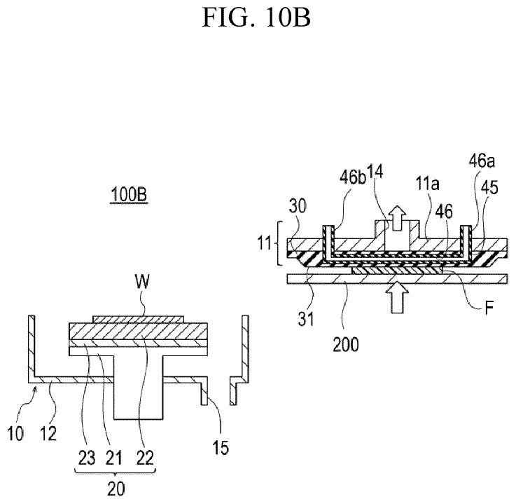

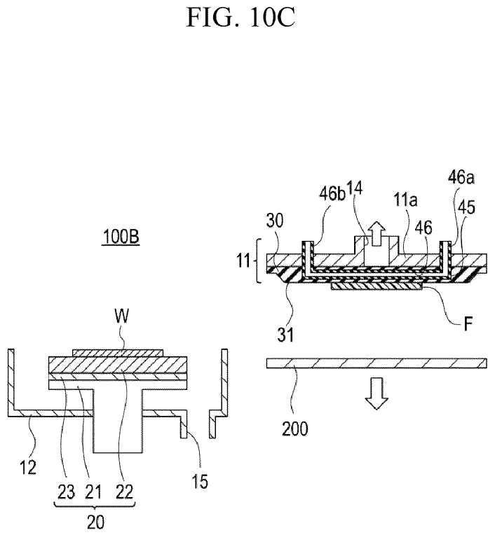

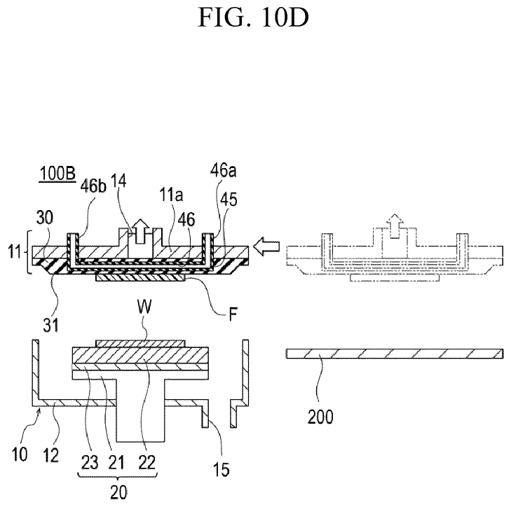

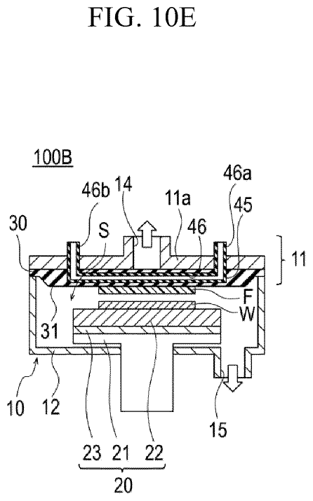

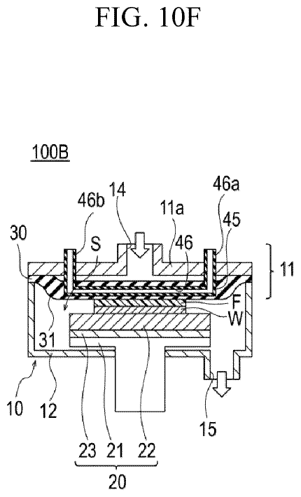

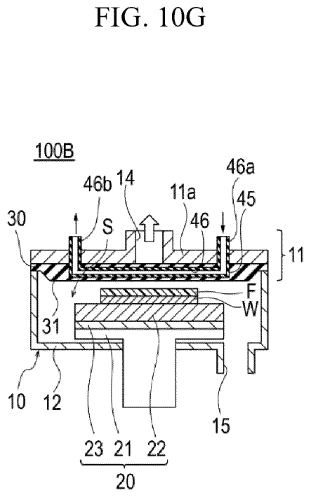

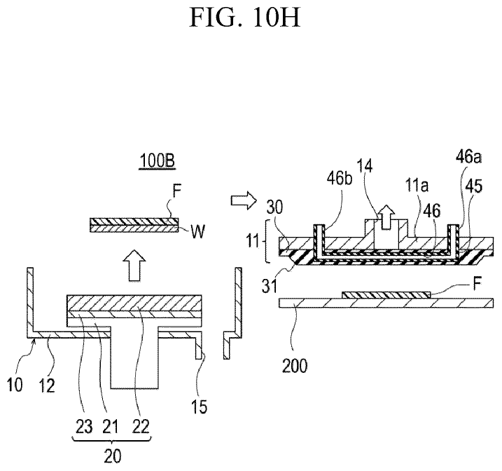

Referring to FIGS. 10A to 10H, process steps S1 to S7 of the flowchart in FIG. 3 may be performed in substantially the same manner as those described with reference to FIGS. 7A to 7H. Accordingly, repetitive descriptions may be briefly explained or omitted for conciseness, and following description may be focused on the difference therebetween.

As shown in FIG. 10A, the mounting device 100B performs the first moving process S1, mounts the workpiece W on the electrostatic chuck 22, and moves the cover 11 to move to bring the adhesive film F mounted on the mounting stand 200. The mounting device 100 contracts the elastic layer 30 by drawing air from the ventilation hole 14. In addition, the mounting device 100B initiates the operation of the cooling part 46 to cool the elastic layer 30.

As shown in FIG. 10B, the mounting device 100B performs the adsorption process S2, and pressurizes the first surface 31 of the elastic layer 30 on the adhesive film F, to adhere the adhesive film F to the first surface 31. As shown in FIG. 10C, the mounting device 100B performs the second moving process S3 such that it receives the adhesive film F from the mounting stand 200. As shown in FIG. 10D, the cover 11 returns to the upper side of the housing 12. As shown in FIG. 10A to FIG. 10C, the mounting stand 200 moves up and down, at the time of transferring the adhesive film F.

As shown in FIG. 10E, the mounting device 100B performs the processing space forming process S4, relatively moves the cover 11 with respect to the housing 12, and forms the processing space S by being in tight contact with the housing 12. When the processing space S formed, the mounting device 100 discharges the interior air within the processing space S through the discharge opening 15, to depressurize the processing space S to the predetermined pressure.

As shown in FIG. 10F, the mounting device 100B performs the attaching process S5, and expands the elastic layer 30 by introducing air from the ventilation hole 14. In addition, the mounting device 100B raises the stage 20 toward the cover 11 in accordance with the expansion of the elastic layer 30. At this time, the adhesive film F becomes highly adhesive to the heated workpiece W by being in contact, and is thus attached to the attachment surface Wa of the workpiece W from the first surface 31 of the elastic layer 30. In addition, the adhesive film F is attached to the attachment surface Wa of the workpiece W while following the deformation of the elastic layer 30, so that void is not formed.

As shown in FIG. 10G, the mounting device 100B performs the cooling process S6, and when the attachment of the adhesive film F is completed, the chamber 10 is opened to the atmosphere and the air in the interior of the cover 11 is discharged from (through) the ventilation hole 14, thereby contracting the elastic layer 30. In addition, simultaneously with the opening to the atmosphere, the mounting device 100B drives the cooling part 46 to cool the elastic layer 30. The cooling part 46 conducts the refrigerant through the fluid line 46. The entire elastic layer 30 may be cooled by the refrigerant circulating through the fluid line 46.

Thereafter, referring to FIG. 10H, the mounting device 100B moves the cover 11, in order to move to bring the subsequent adhesive film F. Since the elastic layer 30 has been cooled by the cooling part 46, when the adhesive film F is adhered to the first surface 31, an unintentional increase of adhesiveness is prevented.

Thereafter, the mounting device 100B repeats the operation shown in FIG. 10A to FIG. 10H, to attach the adhesive film F to the workpiece W. That is, the mounting device 100B determines, at S7, whether a subsequent film attachment processing may be performed. When proceeding to the subsequent film attachment processing (S7—Yes), the mounting device 100A returns back to S1, to perform the subsequent film attachment processing. In addition, when the subsequent film attachment processing is not proceeded, i.e., the processing is not performed (S7-No), the processing is terminated.

Subsequently, the modified example of the mounting device according to the present embodiment will be described. The modified example below may be implemented through an appropriate addition to the above-described mounting devices 100, 100A, and 100B.

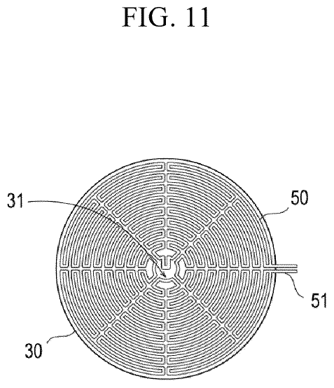

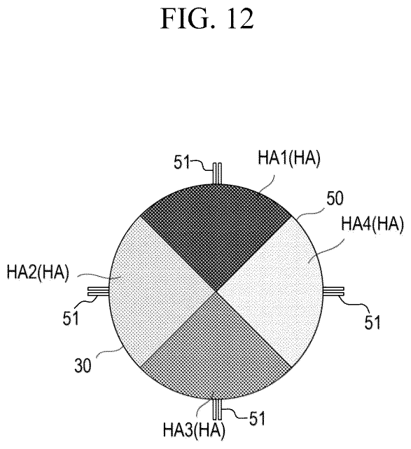

A first modified example in the present embodiment will be described. As a first modified example, the mounting devices 100, 100A, and 100B may include an auxiliary heating part (an auxiliary heater) 50 shown in FIG. 11 and FIG. 12. For example, the auxiliary heating part 50 may be disposed on the first surface 31 of the elastic layer 30 of one of the mounting devices 100, 100A, and 100B described above.

As shown in FIG. 11, the auxiliary heating part 50 may be a heater in which a wiring (wiring pattern) 51 is formed in a predetermined pattern shape on the first surface 31 of the elastic layer 30, by a conductive resin having the same material as the elastic layer 30 as a base material. In some embodiments, the auxiliary heating part 50 may be formed of a conductive resin, and the elastic layer 30 may be formed of a non-conductive material. In some embodiments, the auxiliary heater 50 may be one of a resistance heater (electric heater) using a metal conductor or a thin-film conductor which act as a heating element when current flows therethrough it, an inductive heater using electromagnetic induction to heat a conductive material (usually the chuck itself), a thermal conduction heater using heat transfer from a heated source to the chuck, a plasma heater using the energy from plasma source, an infrared (IR) heater using radiant energy, a Peltier (thermoelectric) heater using the Peltier effect, and so on. For example, in response to a predetermined voltage applied to the wiring 51, the auxiliary heating part 50 may heat the elastic layer 30 since the wiring 51 generates heat by the wire resistance of the wiring 51.

As shown in FIG. 11, the auxiliary heating part 50 may be formed over most of the entire portion of the elastic layer 30. The auxiliary heating part 50 may act to achieve auxiliary heating the adhesive film F. For example, the auxiliary heating part 50 may heat the elastic layer 30 and the adhesive film F. In some embodiments, the auxiliary heating part 50 may be formed only in a central portion of the elastic layer 30, depending on the size or shape of the used adhesive film F. For example, in some embodiments, the auxiliary heating part 50 may be formed in a central portion of the elastic layer 30 such that the auxiliary heating part 50 may be in contact with the adhesive film F which is secured on the elastic layer 30. Additionally, the auxiliary heating part 50 may be at the vicinity of the adhesive film F. Accordingly, the adhesiveness of the adhesive film F may be efficiently increased. For example, the heating temperature of the heating part 23 is set to a first temperature (e.g., 100° C.), the auxiliary heating part 50 may be set to a second temperature (about 80° C.), and the second temperature may be lower than the first temperature.

As shown in FIG. 12, the auxiliary heating part 50 formed on the first surface 31 of the elastic layer 30 may be partitioned into a plurality of heating regions HA, and the wiring 51 may be independently patterned in each of the heating regions HA (i.e., HA1 to HA4). Accordingly, the first surface 31 of the elastic layer 30 may appropriately select and heat the shape of the adhesive film F or a region requiring auxiliary heating. For example, the heater may be disposed on the plurality of heating regions (corresponding to HA1 to HA4) of the first surface 31 of the elastic layer 30, and may be configured to heat the plurality of heating regions HA1 to HA4 independently.

In addition, the heating region HA is not limited to the partitioned shape and the partition quantity shown in FIG. 12. In addition, in the heating region HA, although the wiring 51 is patterned for each region, the wiring 51 may be patterned over a plurality of regions. For example, the wiring pattern 51 may be a plurality of conductive resin patterns.

As described above, the mounting devices 100, 100A, and 100B may be configured with the auxiliary heating part 50 installed in the elastic layer 30. Accordingly, when attaching the adhesive film F to the workpiece W, the mounting devices 100, 100A, and 100B may auxiliary heat the adhesive film F secured on the elastic layer 30, in addition to the heating from the stage 20. Accordingly, since the mounting devices 100, 100A, and 100B can securely increase the adhesiveness of the adhesive film F, the attachment defect with respect to the workpiece W may be prevented.

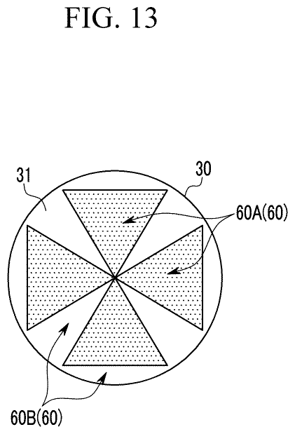

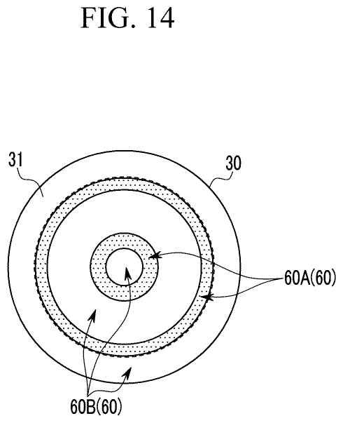

A second modified example according to the present embodiment will be described. As a second modified example, as shown in FIG. 13 and FIG. 14, each of the mounting devices 100, 100A, and 100B may include an elastic layer 30, the first surface 31 of which has a plurality of regions (adsorption surfaces 60) having different adsorption forces from each other.

As shown in FIG. 13, the adsorption surface 60 may include first adsorption surfaces 60A and a second adsorption surface 60B. The first adsorption surfaces 60A may be a plurality of triangular regions extending from (and sharing) a central of the elastic layer 30 toward an exterior circumference. Each of the plurality of triangular regions may have a predetermined side. The predetermined sides may be disposed along the exterior circumference with equal intervals. For example, as shown in FIG. 13, four of the triangular regions may be substantially evenly disposed at 90° intervals, rotating around the center of the elastic layer 30 in a plan view.

As for the arrangement form of the adsorption surface 60, regions having different surface roughness in concentric circles as shown in FIG. 14 may be alternately disposed from a central side toward an exterior circumference. For example, the elastic layer 30 shown in FIG. 14 may have an adsorption surface 60, which is configured to contact the adhesive film. The adsorption surface 60 may be divided into concentric regions 60A and 60B, resembling an archery target. Each of the concentric regions 60A and 60B may have a different surface roughness. As for the adsorption surface 60, in addition to the examples shown in FIG. 13 or FIG. 14, a plurality of regions having different adsorption forces may be disposed in any shape, depending on the shape, size, or the like of the used adhesive film F.

In the adsorption surface 60, a plurality of regions having different adsorption forces depending on a difference of a surface roughness of the first surface 31 may be formed. For example, an adsorption surface 60 may correspond to the first surface 31 of the elastic layer 30. In some embodiments, an adsorption surface 60 may include additional material formed on at least a portion of the first surface 31. In some other embodiments, the plurality of regions of the adsorption surface 60 may be formed of different material (having different adsorption force) from each other.

For example, in the adsorption surface 60, the adsorption force of each surface may be varied by adjusting the number of pits, recess portions or convex portions formed on the first surface 31, such that the adsorption force and/or the arrangement shape of the regions may be varied depending on the size of area in contact with the adhesive film F.

As an example, in the adsorption surface 60, a low adsorption region 60A (a region having a large dot size in FIG. 13 and FIG. 14) having high surface roughness may be set to satisfy Ra<10 μm, and a high adsorption region 60B (a region having a small dot size in FIG. 13 and FIG. 14) having low surface roughness may be set to satisfy Ra<1 μm. In some embodiments, Ra (Arithmetic Average Roughness) of the low adsorption region 60A may be equal or greater than 1 μm and less than 10 μm.

In the adsorption surface 60, a plurality of regions having different adsorption forces depending on a difference of friction coefficient of a material forming the first surface 31 may be formed. As for the elastic layer 30, materials having different adsorption forces may be disposed and formed into a predetermined shape such that the adsorption force may vary within the first surface 31 during the forming. In addition, the adsorption force of the adsorption surface 60 may be changed by applying a material having a different friction coefficient to the first surface 31. As an example, as for the adsorption surface 60, a fluorinated resin or the like having low friction coefficient may be applied to the first surface 31 of the elastic layer 30, and the adsorption force of each surface may be changed by forming the low adsorption region 60A being an application area and the high adsorption region 60B being a non-application area. For example, the elastic layer 30 may have a plurality of regions including a first region 60A and a second region 60B. The first region 60A may include a fluorinated resin, and the adsorption force of the second region 60B is higher than the first region 60A.

In some embodiments, as for the adsorption surface 60, although the adsorption force is changed according to the difference in surface roughness or the difference of the friction coefficient of formation material, the adsorption force may be adjusted by combining them. For example, the adsorption surface 60 may have a plurality of regions, which are formed of a different material (or combination of material) having different friction coefficients.

In addition, as for the adsorption surface 60, a configuration having a plurality of regions having different adsorption may be provided by using other factors than the surface roughness and the friction coefficient of material, as long as such modifications do not deviate or depart from the spirit and scope of the present invention. In addition, the adsorption surface 60 is not limited to the two types of the low adsorption region 60A and the high adsorption region 60B, and may form a plurality of adsorption regions in which the adsorption force is set stepwise. For example, the adsorption surface 60 may have first, second and third adsorption regions, which have different adsorption forces. The second adsorption region is disposed between the first and third adsorption regions. The first, second and third adsorption regions have first, second and third adsorption forces, respectively. The first adsorption force may be greater than the second adsorption force. The second adsorption force may be greater than the third adsorption force.

As described above, the mounting devices 100, 100A, and 100B may be a configuration having the plurality types of the adsorption surfaces 60 including regions having different adsorption forces on the first surface 31 of the elastic layer 30. Accordingly, since the adsorption force of the elastic layer 30 can be controlled when attaching the adhesive film F to the workpiece W, the mounting devices 100, 100A, and 100B may be easily peeled off from the elastic layer 30. Accordingly, the mounting devices 100, 100A, and 100B may be securely attached to the workpiece W without the adhesive film F remaining adhered to the elastic layer 30. For example, since the adsorption force of the elastic layer 30 may be controlled (adjustable) depending on the type and/or shape of the adhesive film F, the adhesive film F may be easily peeled off from the elastic layer 30. In addition, after the attaching, a residue of the adhesive film F may not remain and may not be adhered to the elastic layer 30.

In addition, though not shown in the drawings, the above-described mounting devices 100, 100A, and 100B may be provided with an injection device that injects air to the first surface 31 of the elastic layer 30. Accordingly, in the mounting devices 100, 100A, and 1001B, since the cooling effect by the injection device is added in addition to the cooling by the cooling part, the elastic layer 30 may be cooled more efficiently in a shorter time.

As described above, the mounting device according to the present embodiment is an apparatus for adhering the adhesive film F to the attachment surface Wa of the workpiece W. The apparatus may include the housing 12 and the cover 11 detachably coupled to the housing. For example, the chamber 10 may be configured such that the cover 11 and the housing 12 are detachably coupled, and configured to attach the adhesive film F to the workpiece W under a depressurized condition. The apparatus may further include the holding part (the electrostatic chuck 22) accommodated in the chamber 10 and maintaining the workpiece W, and the stage 20 having the heating part 23 for heating the workpiece W. The housing 12 has the discharge opening 15 for depressurizing the interior of the chamber 10, and the cover 11 is configured to include the elastic layer 30, the base portion 11a, and the cooling part. The elastic layer 30 is disposed at a position facing a holding part of the stage 20, is formed of an elastic member capable of maintaining the adhesive film F, and has the first surface 31 capable of attaching the adhesive film F on the attachment surface Wa of the workpiece W, and the second surface 32 opposite to the first surface 31. For example, the elastic layer 30 may be disposed at a lower surface of the cover body 11a to face the holding chuck 22 of the stage 20. The base portion 11a has the A-surface 13 facing the second surface 32 of the elastic layer 30, and the ventilation hole 14 communicating with at least a surface of the A-surface 13 and the exterior of the chamber 10. The cooling part cools the elastic layer 30 by being in contact with the elastic layer 30.

With such a configuration, the mounting device may appropriately cool the elastic layer 30 by the cooling part when performing the attachment process, while the elastic layer 30 is the heated by the stage 20 in order to increase the adhesiveness of the adhesive film F before attaching the adhesive film F. Accordingly, the mounting device may securely adsorb the elastic layer 30 without deteriorating the adsorption property, and may accurately determine the position of the workpiece W. In addition, in the mounting device, since the elastic layer 30 is appropriately cooled by the cooling part, when the adhesive film F contacts the first surface 31 of the elastic layer 30, an unintentional reaction of the adhesive does not occur. Accordingly, according to the mounting device, a bonding defect of the adhesive film F does not occur during the bonding. Furthermore, the mounting device 100 performs an appropriate cooling by the cooling part before moving to bring the subsequent adhesive film F, the cooling time is not long and the productivity is not deteriorated unlike the conventional air injection.

What is claimed is:

1. An apparatus for manufacturing a semiconductor device, the apparatus configured to attach an adhesive film to an attachment surface of a workpiece under a depressurized condition, the apparatus comprising:
a chamber including a housing and a cover detachably coupled to the housing; and
a stage accommodated in the chamber, and having a holding chuck configured to secure the workpiece and a first heater configured to heat the workpiece,
wherein the housing has a discharge opening which is configured to depressurize an interior of the chamber,
wherein the cover comprises an elastic layer, a cover body, and a cooling part,
wherein the elastic layer:
is disposed at a lower surface of the cover body to face the holding chuck of the stage,
is configured to secure the adhesive film,
has a first surface configured to attach the adhesive film on the attachment surface of the workpiece, and
has a second surface facing away from the first surface,
wherein the lower surface of the cover body faces the second surface of the elastic layer,
wherein the cover body has a ventilation hole fluidly communicating with the second surface of the elastic layer, and
wherein the cooling part is in contact with the elastic layer.

2. The apparatus of claim 1, wherein the cooling part includes a thermoelectric device disposed between the second surface and the lower surface.

3. The apparatus of claim 1, wherein the cooling part is a cooling plate disposed on the lower surface and configured to flow a refrigerant through the cooling plate.

4. The apparatus of claim 1, wherein the cooling part is a refrigerant fluid line disposed in an interior of the elastic layer.

5. The apparatus of claim 1, wherein the elastic layer has a second heater configured to heat the adhesive film.

6. The apparatus of claim 5, wherein the second heater has a wiring pattern formed of a conductive resin, and formed on the first surface of the elastic layer.

7. The apparatus of claim 6, wherein the second heater is:
disposed on a plurality of heating regions of the first surface of the elastic layer, and
configured to heat the plurality of heating regions independently.

8. The apparatus of claim 1, wherein the adhesive film is a resin film having an insulating property.

9. The apparatus of claim 1, wherein the elastic layer is a diaphragm formed of silicon rubber.

10. The apparatus of claim 1, wherein:
the first surface of the elastic layer has a plurality of regions, and
with respect to the adhesive film, the plurality of regions have different adsorption forces from each other.

11. The apparatus of claim 10, wherein the plurality of regions have different surface roughness from each other.

12. The apparatus of claim 10, wherein the plurality of regions have different friction coefficients of the first surface from each other.

13. The apparatus of claim 1 further comprising a controller configured to execute:
an adsorption process of adsorbing the adhesive film on the first surface of the elastic layer;
coupling the cover and the housing to provide a processing space in the chamber;
expanding the elastic layer by at least one of:
a processing of depressurizing the interior of the chamber, and
a processing of introducing gas from the ventilation hole to the interior of the chamber; and
a cooling process of cooling the elastic layer by the cooling part after attaching the adhesive film to the workpiece mounted on the stage.

14. An apparatus for manufacturing a semiconductor device, the apparatus configured to attach an adhesive film to an attachment surface of a workpiece, the apparatus comprising:
a chamber comprising a housing and a cover relatively movable with respect to the housing; and
a stage accommodated in the chamber,
wherein the stage is configured to secure the workpiece, and to be relatively movable with respect to the cover,
wherein the cover is configured to contact the housing to provide a processing space in the chamber, and comprises an elastic layer, a cover body, and a cooling part,
wherein the processing space is configured to attach the adhesive film to the workpiece,
wherein the elastic layer:
is disposed at a lower surface of the cover body to face the stage,
has a first surface configured to attach the adhesive film on the attachment surface of the workpiece,
has a second surface which is facing away from the first surface,
is configured to be deformed to follow a surface shape of the attachment surface of the workpiece, and
is configured to deform the adhesive film to follow a shape of the elastic layer,
wherein the lower surface faces the second surface of the elastic layer,
wherein the cover body has a ventilation hole fluidly communicating with the second surface of the elastic layer,
wherein the cooling part is disposed between the second surface of the elastic layer and lower surface of the cover body, and
wherein the cooling part is configured to cool the elastic layer.

15. The apparatus of claim 14, wherein:
the first surface of the elastic layer has a plurality of regions, and
with respect to the adhesive film, the plurality of regions have different adsorption forces as each other.

16. The apparatus of claim 15, wherein:
the plurality of regions include a first region and a second region,
the first region includes a fluorinated resin, and
the adsorption force of the second region is higher than the first region.

17. An apparatus for manufacturing a semiconductor device, the apparatus configured to attach an adhesive film to an attachment surface of a workpiece, the apparatus comprising:
a chamber comprising a housing having a discharge opening and a cover relatively movable with respect to the housing; and
a stage having a stage main body accommodated in the chamber, a holding chuck configured to secure the workpiece, and a heater configured to heat the workpiece,
wherein the cover is configured to contact with the housing to provide a processing space in the chamber,
where the processing space is configured to:
attach the adhesive film to the workpiece within the processing space under a depressurized condition, and
adjust the discharge opening to provide the depressurized condition,
wherein the stage is configured to be relatively movable with respect to the cover,
wherein the cover comprises an elastic layer, a cover body having a ventilation hole, and a cooler,
wherein the elastic layer:
is disposed at a lower surface of the cover body to face the holding chuck of the stage,
has a first surface configured to secure the adhesive film,
has a second surface facing away from the first surface,
is configured to be deformed to follow a surface shape of the attachment surface of the workpiece,
is configured to deform the adhesive film to follow a shape of the elastic layer, and
is configured to expand and to contract such that the adhesive film is deformed to follow the expansion or contraction of the elastic layer,
wherein the cover is configured to introduce gas through the ventilation hole to expand the elastic layer,
wherein the cover is configured to discharge gas through the ventilation hole to contract the elastic layer, wherein the lower surface faces the second surface of the elastic layer,
wherein the cooler is disposed between the second surface of the elastic layer and the lower surface of the cover body, and
wherein the cooler is in contact with the elastic layer and configured to cool the elastic layer.

18. The apparatus of claim 17, wherein the heater is configured to heat the holding chuck, and to heat the workpiece through the holding chuck.

19. The apparatus of claim 17, wherein the cooler include a Peltier element.

20. The apparatus of claim 17, wherein:
the elastic layer comprises a groove on the second surface, and
the cooler is disposed in the groove.
